(19) United States
(12) Patent Application Publication
(10) Pub. No.: US 2011/0095773 A1
(43) Pub. Date: Apr. 28, 2011

(54) COOLING STRUCTURE FOR A TEST DEVICE, AND A METHOD FOR TESTING A DEVICE

(75) Inventor: Hajime MATSUZAWA, Tokyo (JP)

(73) Assignee: NEC CORPORATION, Tokyo (JP)

(21) Appl. No.: 12/910,506

(22) Filed: Oct. 22, 2010

(30) Foreign Application Priority Data
Oct. 26, 2009 (JP) 2009-245486

(51) Int. Cl. G01R 31/10

(52) U.S. Cl. 324/750.09

(57) ABSTRACT

An exemplary embodiment of the present invention aims at providing a cooling structure for a test device which has sufficient cooling performance and can reduce the size of the heat sink. The cooling structure for a test device has first and second plates, a cover with a hole on the first plate, and a heat sink attached to the cover. When the vacuum suction is applied in a test space which is formed between the first and the second plates, air is drawn through the hole of the cover and applied onto the heat sink.

This application is based upon and claims the benefit of priority from Japanese patent application No. 2009-245486, filed on Oct. 26, 2009, the disclosure of which is incorporated herein in its entirety by reference.

### BACKGROUND

The present invention relates to a cooling structure for a test device and a method for testing a device. More particularly, it, relates to a cooling structure of an in-circuit test fixture that cools a device in an in-circuit tester which brings a probe into contact with a circuit substrate to be tested, which extracts a signal through the probe, and which tests a circuit.

A known technique for using an in-circuit test fixture is described below. The technique is that a device to be tested is set up on a table, the same electric power and signal as those in a state where the device is mounted on real equipment are input to the device, and a test is conducted while a probe located on the table is brought into contact with a predetermined test point on a circuit substrate to be tested.

JP-A-S59-6552 discloses a related “multi-pin prober”. In the multi-pin prober, after the circuit substrate to be tested on which the device is mounted has been set up on a test fixture main body, a vacuum suction is applied in a space surrounded between the circuit substrate to be tested and the prober. As a result, a probing pad contacts a contact pin on the prober and the device test is conducted. In this situation, a heater/cooler which is located below the prober is driven under control so as to prevent a positional displacement caused by a difference in thermal expansion between the circuit substrate to be tested and the prober due to heating of the device on the circuit substrate to be tested. On the other hand, JP-A-H11-145349 discloses a technique in which a heat sink is located on a heating member (a device in the case of JP-A-S59-6552), and a cooling air is fed to a fin disposed on the heat sink at a low level to generate a convection.

In addition to the in-circuit test fixture disclosed in JP-A-S59-6552, a technique illustrated in FIG. 3 is known.

An in-circuit test fixture 50 illustrated in FIG. 3 conducts the test in such a manner that a circuit substrate S having a device D is held in a test space 60 between a top probe plate 51 and a bottom probe plate 52, and probes 53 and 54 are applied to the circuit substrate S to apply and observe an electric signal from a tester.

The top probe plate 51 and the bottom probe plate 52 are so disposed as to come closer to or go away from the circuit substrate S which is disposed in an intermediate portion thereof as indicated by arrows A-B. When the test space 60 is sucked by vacuum as indicated by symbol C, the top probe plate 51 and the bottom probe plate 52 approach each other, and the probes 53 and 54 disposed on the plates 51 and 52 contact the circuit substrate S having the device D.

On the other hand, a cover 55 is disposed on the top probe plate 51 at a side where the device D on the circuit substrate S is arranged so as to sandwich a notch 51A. A heat sink 58 that is urged by springs 57 each inserted into a pin 56 in a direction indicated by an arrow A is disposed within the cover 55. When vacuum suction within the test space 60 indicated by the symbol C allows the top probe plate 51 and the bottom probe plate 52 to approach each other, the heat sink 58 comes in close contact with the device D on the circuit substrate S.

Since the above-mentioned test space 60 within the fixture including the cover 55 is of a sealed structure, in applying the probes 53 and 54 to the circuit substrate S, a vacuum system in which the circuit substrate 5 is held between the top probe plate 51 and the bottom probe plate 52 by the aid of the vacuum suction C to apply the probes 53 and 54 is most popularly employed. In such vacuum suction C, the probes 53 and 54 stop at the time of contacting the circuit substrate S. However, because the entire testing space is in a sealed structure, the test space 60 within the fixture comes to a state close to vacuum, and the probes 53 and 54 are kept in contact with the circuit substrate S.

In the in-circuit thus configured, there is a structure in which the circuit structure S is cooled by natural cooling not using the above-mentioned heat sink 58. However, there is a case in which a large amount of heat is generated from the device D by higher processing speed and higher integration of LSI, which cannot be dealt with by the natural cooling.

As a countermeasure thereagainst, it is conceivable that, for example, a fan indicated by symbol 61 is fitted to the heat sink 58. However, because the sealed space 60 of the in-circuit test fixture 50 is close to vacuum, a problem arises such that even if the fan 61 is fitted thereto, the convection of air is not generated, and sufficient cooling cannot be obtained. Further, when the size of the heat sink 58 is increased in order to obtain a sufficient cooling performance, a problem arises in that a sufficient space for location of the probes 53 and 54 cannot be ensured around the circuit substrate S having the device D.

The present invention has been made in view of the above-mentioned circumstances, and aims at providing a cooling structure of an in-circuit test fixture which has sufficient cooling performance and can reduce the size of the heat sink.

### SUMMARY OF THE INVENTION

An exemplary object of the present invention is to provide a cooling structure for a test device, and a method for testing a device which has sufficient cooling performance and can reduce the size of the heat sink.

According to a non-limiting illustrative embodiment, a cooling structure for a test device comprising: a first probe plate; a second probe plate; a cover on the first probe plate; a probe on at least one of the first and second probe plates; and a heat sink attached to the cover; wherein the cover has a hole, wherein a test space is formed between the first and second plates, wherein the probe is capable of connecting to a device to be tested when a vacuum suction is applied to the test space, and wherein when the vacuum suction is applied, air is drawn through the hole and applied onto the heat sink.

According to another non-limiting illustrative embodiment, a method of cooling a device being tested comprising: placing the device in a test space formed between a first probe plate and a second probe plate, and applying a vacuum suction to the test space, wherein when the vacuum is applied, a probe on at least one of the first and second probe plates connects to the device, and wherein when the vacuum is applied, air is drawn through a hole in a cover on the first probe plate and the air is applied to a heat sink attached to the cover.

### BRIEF DESCRIPTION OF THE DRAWING

Other features and advantages of various embodiments of the present invention will become apparent by the following detailed description and the accompanying drawing, wherein:

FIG. 1 is a front view including a partial cross section of the cooling structure for a test device in the first exemplary embodiment of the present invention.

FIG. 2 is a plan view of a cover illustrated from the upper side of FIG. 1.

FIG. 3 is a front view including a partial cross section of the cooling structure for a test device in the related art.

### DETAILED DESCRIPTION

The present invention will now be described more fully with reference to the accompanying drawings, in which examples of embodiments of the invention are shown. The invention may, however, be embodied in many different forms and should not be construed as being limited to the embodiments set forth therein; rather, these examples of embodiments are provided so that this disclosure will be thorough and complete, and will fully convey the concept of the invention to those skilled in the art.

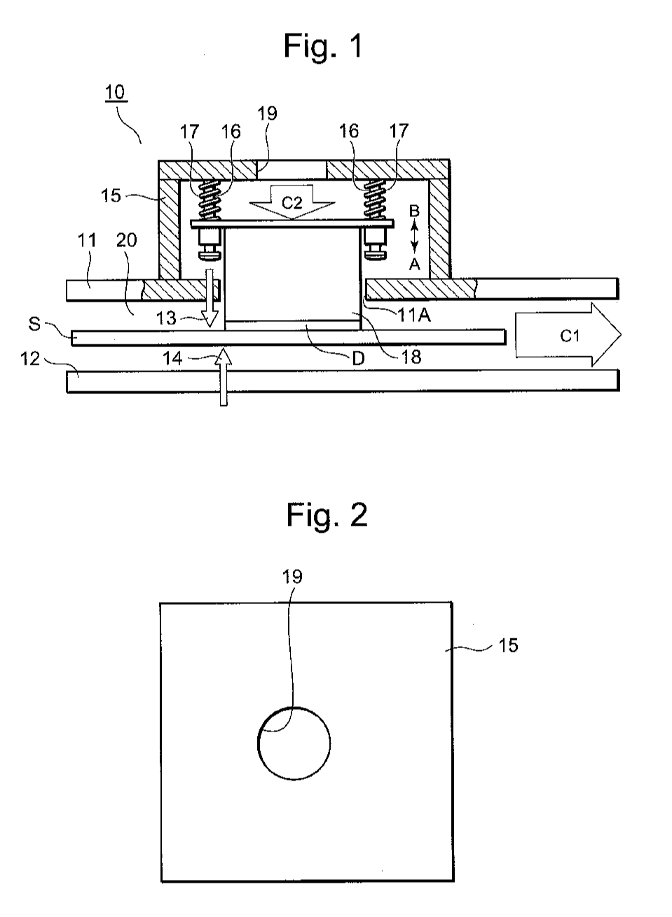

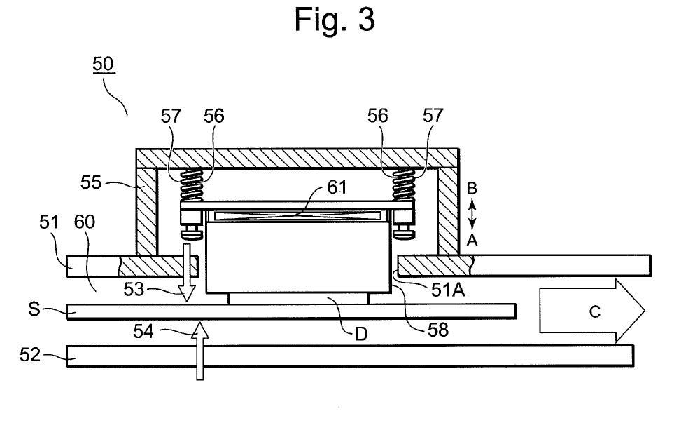

A first exemplary embodiment of the present invention will be described in detail with reference to FIGS. 1 and 2.

An in-circuit test fixture 10 shown in FIG. 1 includes a top probe plate 11 and a bottom probe plate 12 which are so disposed as to come closer to or go away from each other as indicated by arrows A-B. In an in-circuit test, a circuit substrate S on which a device D is mounted is held in an intermediate portion between the top probe plate 11 and the bottom probe plate 12.

Also, the top probe plate 11 and the bottom probe plate 12 are equipped with probes 13 and 14, respectively. When the circuit substrate S is held between the top probe plate 11 and the bottom probe plate 12, the respective probes 13 and 14 are brought into contact with test points on the circuit substrate S, to thereby apply and observe an electric signal from a tester through the probes 13 and 14 to implement the test of the circuit substrate S.

Also, the test space 20 between the top probe plate 11 and the bottom probe plate 12 is connected to a vacuum source (not shown). When the test space 20 is sucked by vacuum as indicated by symbol C1, the top probe plate 11 and the bottom probe plate 12 come closer to each other, and the probes 13 and 14 which are disposed on the plates 11 and 12, respectively, contact the test points of the circuit substrate S.

A cover 15 is disposed on the top probe plate 11 at a side where the device D on the circuit substrate S is arranged so as to sandwich a notch 11A. A heat sink 18 that is urged by springs 17 each inserted into a pin 16 in a direction indicated by an arrow A is disposed within the cover 15.

The pins 16 are arranged along the directions indicated by the arrows A-B which are orthogonal to the plates 11 and 12, and the heat sink 18 is so disposed as to be movable along the pins 16 in the directions indicated by the arrows A-B. Also, the springs 17 are compression springs each formed in a coil shape, and are arranged between the cover 15 and the heat sink 18 to urge the heat sink 18 in the direction indicated by the arrow A.

Then, when the vacuum suction indicated by the symbol C1 allows the top probe plate 11 and the bottom probe plate 12 to approach each other, the urging of the spring 17 brings the heat sink 18 into close contact with the device D on the circuit substrate S.

The cover 15 is provided with a suction hole 19 for taking in external air.

As shown in FIG. 2, the suction hole 19 is circular. The suction hole 19 is arranged at an upper side of the cover 15 so as to face an upper surface of the heat sink 18. Then, air taken in from outside the test fixture as indicated by symbol C2 through the suction hole 19 when the test space 20 is subjected to vacuum suction C1 is introduced into the cover 15, and blown to the heat sink 18 located in the cover 15. As a result, the heat sink 18 is cooled. The size of the suction hole 19 is determined on the basis of the vacuum suction, and the number and position of the probes 13 and 14 so that no problem arise with the contact of the probes 13, 14 and the circuit substrate S.

The action of the in-circuit test fixture configured as described above will now be described.

First, when vacuum suction is conducted as indicated by the symbol C1, the top probe plate 11 and the bottom probe plate 12 approach each other, and the probes 13 and 14 disposed on the plates 11 and 12, respectively, contact the test points of the circuit substrate S. In this state, the device D and the circuit substrate S are tested and observed. In this situation, the suction of the external air from the suction hole 19 as indicated by the symbol C2 allows air to be applied onto the upper surface of the heat sink 18, thereby preventing the overheat of the heat sink 18.

Also, the vacuum suction C1 is continued even after the probes 13 and 14 contact the circuit substrate S, to thereby continue the suction of the external air from the suction hole 19 as indicated by the symbol C2. As a result, because air is constantly applied to the upper surface of the heat sink 18, overheating of the heat sink 18 is prevented, and the cooling performance of the heat sink 18 does not deteriorate. Thereafter, upon completion of the device test, the vacuum suction C1 stops, and the circuit substrate S is released.

As has been described above, according to the in-circuit test fixture described in this embodiment, the cover 15 having the heat sink 18 for cooling the device D therein is disposed on the probe plate 11 at the side where the device D on the circuit substrate S is arranged. Also, the cover 15 is provided with the suction hole 19 for taking in the external air. Therefore, when the test space 20 is subjected to the vacuum suction C1, the external air taken in through the suction hole 19 is introduced into the heat sink 18 (symbol C2) within the cover 15, to thereby cool the heat sink 18. As a result, as compared with the conventional in-circuit test fixture that fans air by the fan under vacuum, the heat sink 18 can be efficiently cooled, and the heat sink 18 can be reduced in size. In the above embodiment, the suction hole 19 is circular. However, the shape is not limited to a circle, but may be shaped, for example, as a rectangle or a triangle. Also, the number of suction holes 19 is not limited to one, but a plurality of suction holes 19 may be formed. Also, the suction hole 19 is not limited to being placed on the upper portion of the cover 15, but may be disposed at a side of the cover 15 as long as air sucked from outside the test fixture is applied to the heat sink 18.

Also, the number and size of the suction holes 19 are determined on the basis of the vacuum suction and the number and position of the probes 13 and 14 so that no problems arise with the contact of the probes 13 and 14 with the circuit substrate S.

The embodiment of the present invention has been described above in detail with reference to the drawings. However, specific configurations are not limited to this embodiment, and the design can be modified without departing from the subject matter of the present invention.

What is claimed is:

1. A cooling structure for a test device comprising:
a first probe plate;
a second probe plate;
a cover on the first probe plate;
a probe on at least one of the first and second probe plates; and
a heat sink attached to the cover;
wherein the cover has a hole,
wherein a test space is formed between the first and second plates,
wherein the probe is capable of connecting to a device to be tested when a vacuum suction is applied to the test space, and
wherein when the vacuum suction is applied, air is drawn through the hole and applied onto the heat sink.

2. The cooling structure according to claim 1,
wherein the test space is configured to hole the device on a circuit substrate, and
wherein when the vacuum suction is applied, the probe is capable of connecting to the circuit substrate.

3. The cooling structure according to claim 1,
wherein the heat sink is capable of moving toward and away from the device.

4. The cooling structure according to claim 1,
wherein the probe is on the first plate, and
wherein when the vacuum suction is applied, the first plate moves closer to the second plate.

5. The cooling structure according to claim 4,
wherein the probes are on both the first and second plates, and
wherein when the vacuum suction is applied, the distance between the first plate and the second plate becomes smaller.

6. The cooling structure according to claim 1,
wherein the hole is located at an upper side of the cover so as to face an upper surface of the heat sink.

7. The cooling structure according to claim 1,
wherein a plurality of holes are provided on the cover.

8. The cooling structure according to claim 1,
wherein the hole is in the shape of circle.

9. The cooling structure according to claim 1, further comprising:
an elastic device between the heat sink and the cover.

10. The cooling structure according to claim 9,
wherein the elastic device creates a downward force on the heat sink when the first probe plate moves toward the device.

11. A method of cooling a device being tested comprising:
placing the device in a test space formed between a first probe plate and a second probe plate, and
applying a vacuum suction to the test space,
wherein when the vacuum is applied, a probe on at least one of the first and second probe plates connects to the device, and
wherein when the vacuum is applied, air is drawn through a hole in a cover on the first probe plate and the air is applied to a heat sink attached to the cover.

12. The method of cooling according to claim 11,
wherein the device is on a circuit substrate in the test space, and
wherein when the vacuum suction is applied, the probe connects to the circuit substrate.

13. The method of cooling according to claim 12,
wherein the heat sink is capable of moving toward and away from the device.

14. The method of cooling according to claim 12,
wherein the probe is on the first plate, and
wherein when the vacuum suction is applied, the first plate moves closer to the second plate.

15. The method of cooling according to claim 14,
wherein the probes are on both the first and second plates, and
wherein when the vacuum suction is applied, the distance between the first plate and the second plate becomes smaller.

16. The method of cooling according to claim 11,
wherein the hole is located at an upper side of the cover so as to face an upper surface of the heat sink.

17. The method of cooling according to claim 11,
wherein a plurality of holes are provided on the cover.

18. The method of cooling a device being tested according to claim 11,
wherein the hole is in the shape of circle.

19. The method of cooling according to claim 11, further comprising:
placing an elastic device between the heat sink and the cover.

20. The method of cooling according to claim 19,
wherein the elastic device creates a downward force on the heat sink when the first probe plate moves toward the device.
